(19) United States
(12) Patent Application Publication
(10) Pub. No.: US 2011/0006405 A1
(43) Pub. Date: Jan. 13, 2011

(54) SEMICONDUCTOR DEVICE, MANUFACTURE METHOD OF SEMICONDUCTOR DEVICE, AND ELECTRONIC APPARATUS

(75) Inventors: Keiichi YAMAMOTO, Kawasaki (JP); Takashi FUKUDA, Kawasaki (JP)

Correspondence Address: SQUIRE, SANDERS & DEMPSEY L.L.P., 8000 TOWERS CRESCENT DRIVE, 14TH FLOOR, VIENNA, VA, 22182-6212, US

(73) Assignee: FUJITSU LIMITED, Kawasaki-shi (JP)

(21) Appl. No.: 12/818,331

(22) Filed: Jun. 18, 2010

(30) Foreign Application Priority Data
Jul. 7, 2009 (JP) 2009-160552

(51) Int. Cl. H01L 23/00; H01L 21/71

(52) U.S. Cl. 257/629; 438/758; 257/E23.194; 257/E21.536

(57) ABSTRACT

A semiconductor device includes a substrate, an electronic component and a resin member. The substrate has a first electrode. The electronic component is provided on the substrate, and has a second electrode electrically connected to the first electrode. The resin member alleviates an external stress to the second electrode of the electronic component. The resin member is disposed on the substrate at a region separated from the electronic component.

### CROSS-REFERENCE TO RELATED APPLICATION

This application is based upon and claims the benefit of priority of the prior Japanese Patent Application No. 2009-160552, filed on Jul. 7, 2009, the entire contents of which are incorporated herein by reference.

### FIELD

Embodiments discussed herein are related to a semiconductor device, manufacture method of a semiconductor device, and an electronic apparatus.

### BACKGROUND

In certain situations, an external stress may be applied to a substrate (e.g., a printed circuit board) with an electronic component mounted thereon while the substrate is installed to an enclosure or the like with screws or other fasteners. The external stress may propagate on the substrate and generate a continuous creep stress at a solder joint portion between the electronic component and the substrate.

As a result, a rupture in the solder joint portion and/or the exfoliation of a conductive pad on the substrate may occur after the installation in the enclosure. The ball grid array (BGA) has been known as a method of mounting an electronic component onto a substrate. Particularly, since an electronic component having a BGA configuration has a short terminal generally, the electronic component may not adequately endure such external stress.

For reducing the solder joint portion-rupture and/or the pad exfoliation, an underfill application is often performed to pour a resin into a space between an electronic component and a printed circuit board. Further, machining can be performed to attain the configuration reliability after the electronic component mounting. For example, the configuration of a mount substrate including a stiffener with a predetermined thickness, the stiffener being fixed onto the top surface and/or the under surface of the mount substrate through the use of an adhesive and/or screws so that the same effect as that attained through the use of an underfill material is attained, is known.

The above-described technologies are disclosed in, for example, Japanese Laid-Open Patent Applications 1-105593 and 2007-227550.

Once the underfill application is performed on the substrate, however, replacement of the electronic component may be difficult. Therefore, if a substrate where the underfill has been applied before an electric test, fails the electric test, the substrate is typically abandoned or discarded, which may cause a waste of the substrate.

Further, in the case where the stiffener is used, a replacement of the electronic component with another one may also be difficult, which also may cause a waste of the substrate.

### SUMMARY

According to an embodiment of the invention, a semiconductor device is provided with a substrate, an electronic component and a resin member. The substrate has a first electrode. The electronic component is provided on the substrate, and a second electrode is electrically connected to the first electrode. The resin member alleviates an external stress to the second electrode of the electronic component. The resin member is disposed on the substrate at a region separated from the electronic component.

It is to be understood that both the foregoing general description and the following detailed description are exemplary and explanatory, and are not restrictive of the invention.

### BRIEF DESCRIPTION OF DRAWINGS

The above-described and other features of the invention will become apparent from the following description of the embodiments in conjunction with the accompanying drawings, wherein:

FIG. 1A illustrates a substrate unit according to a first embodiment;

FIG. 1B also illustrates the substrate unit according to the first embodiment;

FIG. 2 illustrates an external stress occurring in a substrate due to an external stress applied to an external stress application point;

FIG. 3 illustrates a different pattern of arranging resin member;

FIG. 4 illustrates a different pattern of arranging resin member;

FIG. 5 illustrates a different pattern of arranging resin member;

FIG. 6 illustrates a substrate unit according to a second embodiment;

FIG. 7A illustrates a shape of a resin for measurement;

FIG. 7B illustrates another shape of the resin for measurement; and

FIG. 7C illustrates another shape of the resin for measurement;

FIG. 8 is a graph illustrating the measurement result;

FIG. 9 illustrates a method of manufacturing a substrate unit;

FIG. 10 also illustrates the method of manufacturing the substrate unit;

FIG. 11 illustrates an exemplary stress occurring in a substrate unit manufactured based on a manufacture method according to a second embodiment;

FIG. 12A illustrates a method of determining the positions where resin member are arranged;

FIG. 12B illustrates another method of determining the positions where the resin member is arranged;

FIG. 12C illustrates another method of determining the positions where the resin member is arranged;

FIG. 13 illustrates an exemplary hardware configuration of a simulation device; and

FIG. 14 illustrates the simulation result displayed on a monitor.

### DESCRIPTION OF EMBODIMENTS

Hereinafter, embodiments will be described in detail with reference to the attached drawings.

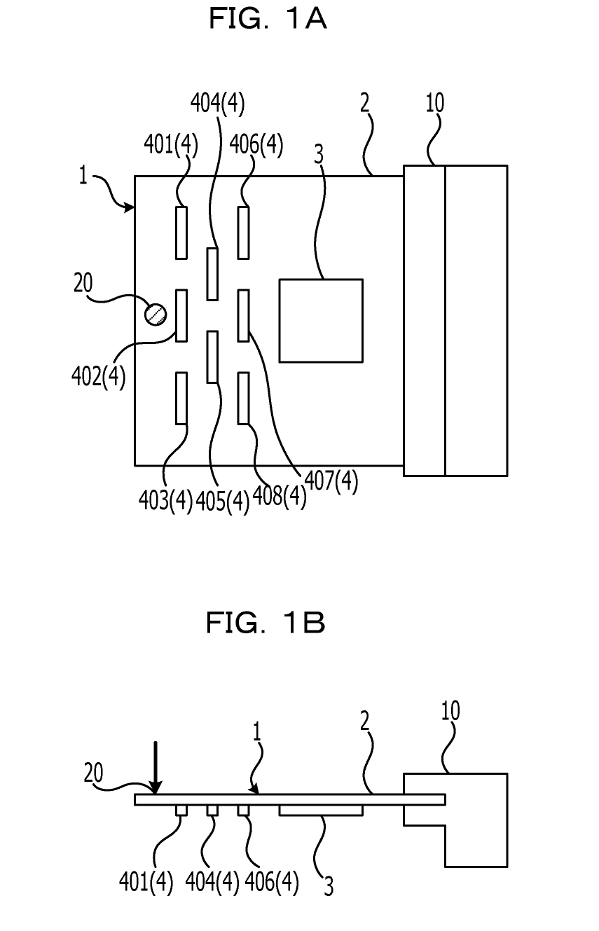

FIGS. 1A and 1B illustrates a substrate unit 1 according to a first embodiment.

FIG. 1A is a plan view illustrating the substrate unit 1 including a flexible substrate 2, an electronic component 3 provided on the substrate 2, and resin member or structures 401, 402, 403, 404, 405, 406, 407, and 408, which may be simply referred to as the resin member 4. Here, the resin members or structures 401 to 408 are designated by different reference numerals for identifying the resin member arranged at the different positions.

The electronic component 3 includes a lead insertion-type package, a surface mount-type package, etc., and includes a plurality of electrodes arranged in a predetermined format. Each above-described electrodes is electrically bonded to an electrode (not shown) provided on the substrate 2 according to the solder-reflow method, for example.

The electronic component 3 may be, for example, a semiconductor integrated circuit such as a central processing unit (CPU), a memory including a random access memory (RAM), etc., a peripheral logic circuit that transmits and/or receives data of the processing result to and/or from a CPU, an interface circuit that transmits and/or receives data to and/or from a peripheral logic circuit.

Further, the surface mount-type package can include, for example, a flat package with gull-wing leads and/or straight leads, a J-lead package, a BGA-type package with or without solder balls, a land grid array (LGA)-type package, a quad flat non-leaded (QFN) package, a small outline non-leaded (SON) package, etc. Each above-described packages includes ceramic, plastic, etc.

Each resin member 4 is in a rectangular shape in plan view and the resin member 4 is provided on a surface of the substrate 2, the surface being the same as that where the electronic component 3 is provided. In FIG. 1A, eight resin members including the resin member 401 to 408 are provided on the above-described surface.

The resin member 4 is provided on the substrate 2 by applying a resin on the substrate 2, for example. Here, the dimensions (the width and the height) of each resin member 4 is dependent on the dimensions of the substrate 2, the dimensions of the electronic component 3, the relationships between each resin member 4 and a different electronic component (not shown), etc., and are not particularly limited. However, the width of each resin member 4 may be from 0.5 mm to 5.0 mm inclusive. Further, the height of each resin member 4 may be from 0.5 mm to 3.0 mm inclusive.

The resin member 4 is regularly arranged at predetermined positions specified on a part other than the part where the electronic component 3 is bonded to the substrate 2. In other words, the resin member 4 is regularly arranged away from the electronic component 3 by as much as a predetermined distance.

In each of FIGS. 1A and 1B, an external stress application point 20 is illustrated. The resin member 4 is arranged so that the stress application point 20 and the electronic component 3 are opposed to each other with the resin member 4 therebetween in plan view.

Further, a plurality of stages, such as three stages, of the resin members 4 are arranged toward the electronic component 3 with reference to the stress application point 20 (from the left side to the right side of FIG. 1). More specifically, the resin member 401, 402, and 403 are arranged at the first stage, the resin member 404 and 405 are arranged at the second stage, and the resin member 406, 407, and 408 are arranged at the third stage.

Further, the resin member 4 is alternately arranged or staggered so that at least parts of the resin member 4 overlap one another, so that no gaps occur when viewed from the left side of FIG. 1. More specifically, the resin 404 is arranged between the resin member 401 and 402, the resin 405 is arranged between the resin member 402 and 403, and the resin 407 is arranged between the resin member 404 and 405 when viewed from the left side of FIG. 1.

The above-described arrangement allows for distributing the stress occurring at the stress application point 20 so that electronic component 3 is prevented from being directly acted upon by the stress. Although the material of each resin member 4 is not particularly limited, the material may be a thermosetting resin including an epoxy resin, an acrylic resin, a urethane resin, a polyimide resin, an unsaturated polyester resin, a phenolic resin, a silicone resin, etc.

Of the above-described resin member, the epoxy resin or an epoxy acrylate resin may be preferable to the others. When the material includes the epoxy resin, the hardness and cohesion (adhesion) of the above-described material is increased. Further, when the material includes the epoxy acrylate resin, the material dries quickly and is cured under a low temperature, for example a room-temperature curing, or the ultraviolet curing.

In FIG. 1, the resin member 4 is arranged on the same surface as that where the electronic component 3 is arranged. Without being limited to the above-described arrangement, however, the resin member 4 may be arranged on a surface opposed to that where the electronic component 3 is arranged. The above-described arrangement also allows for distributing the stress. In that case, the resin member 4 is also arranged so that the stress application point 20 and the electronic component 3 are opposed to each other with the resin member 4 therebetween in plan view.

FIG. 1B is a side view of the substrate unit 1 held by a supporting member 10 in a cantilevered state. In FIG. 1B, an external stress is applied to the stress application point 20 from the upper side to the lower side of the page. Consequently, the substrate unit 1 is bent.

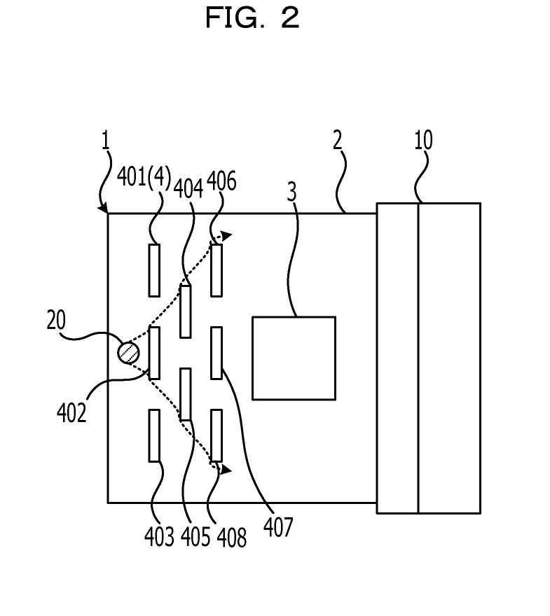

Since the resin member 4 is regularly arranged in the above-described embodiment, an external stress applied to the electronic component 3 is reduced. The above-described stress is less than that applied to the electronic component 3 when the resin member 4 is not provided. FIG. 2 illustrates an external stress occurring in the substrate unit 1 due to the stress applied to the stress application point 20.

Since the substrate unit 1 is held by the supporting member 10, an external stress applied to the stress application point 20 generates an external stress which propagates in a direction so that the generated stress radially propagates from the stress application point 20 toward the supporting member 10. FIG. 2 illustrates an example of the direction in which the generated stress propagates as dotted lines.

When the generated stress acts on the resin member 402, a part of the propagating stress is absorbed by the resin member 402 as illustrated in FIG. 2 so that the propagating stress is reduced and moved along the surface of the resin member 402. After the stress reaches the corner of the resin member 402, a part of the stress acts on the resin member 404 and 405.

When the stress acts on the resin member 404 and 405, a part of the propagating stress is absorbed by the resin member 404 and 405 so that the propagating stress is reduced and moved along the surface of each resin member 404 and 405. When the stress reaches the corner of the resin 404 after that, a part of the stress acts on the resin 406. When the stress reaches the corner of the resin 405, a part of the stress acts on the resin 408.

When the stress acts on the resin member 406 and 408, a part of the propagating stress is absorbed by the resin member 406 and 408 so that the propagating stress is reduced and moved along the surface of each resin member 406 and 408. Then, the stress reaches the corner of each resin member 406 and 408, and propagates toward a side of the substrate 2.

According to the above-described substrate unit 1, the resin member 4 is arranged between the stress application point 20 and the electronic component 3. Therefore, even though the stress acts on the electronic component 3, the stress becomes less than in the past, which makes it possible to protect the electronic component 3 from the stress with facility.

Further, the resin member 4 is arranged away from the electronic component 3 so that the electronic component 3 can be easily mounted or demounted on or from the substrate 2. Further, the joint portion between the electronic component 3 and the substrate 2 is indirectly reinforced with the resin member 4 so that the stress acting on the joint portion is reduced.

Further, at least two of the resin member 4 are arranged with a predetermined gap therebetween so that the stress is more equally distributed than in the case where a single resin is arranged. Still further, compared to the case where the underfill application is performed, for example, the temperature cycle test (temperature accelerated life test) property may be deteriorated depending on the underfill application property. However, the arrangement achieved in the above-described embodiment may avoid the property deterioration.

Further, property variations of a specified component and/or a peripheral component may occur due to an underfill contact. Therefore, it may be difficult to reinforce the joint portion between the specified component and the substrate 2 according to an underfill application. On the other hand, the arrangement of the resin member 4, which is achieved in the above-described embodiment, allows for easily reducing the stress occurring in the electronic component 3 even though the specified component is mounted on the substrate 2.

Further, the case where a stiffener is used will be compared to the above-described embodiment as below. In that case, the stiffener is provided as a structure including the electronic component 3 so that the number of components is increased. Consequently, the circuit area is increased. However, the arrangement of the resin member 4, which is achieved in the above-described embodiment, allows for preventing the circuit area from being increased.

Although not shown in FIG. 2, the widths of the resin member 4 (thicknesses that are defined along a horizontal direction in FIG. 2) may not be equalized. For example, the widths of the resin member 401 to 403 may be greater than those of the resin member 404 to 408. Namely, the widths of the resin member 4 may be varied based on the magnitude of stress acting on the resin member 4.

When the widths of the resin member 401 to 403 are greater than those of the resin member 404 to 408, the stress acting on the latter resin member 404 to 408 may be lower than that illustrated in FIG. 2.

In the above-described embodiment, each resin member 4 is formed with the rectangular shape. However, without being limited to the above-described embodiment, a part of and/or the entire side of each resin member 4 may be curved and/or bent. Further, when a different electronic component is arranged near the electronic component 3, the resin member 4 may be arranged on the different electronic component.

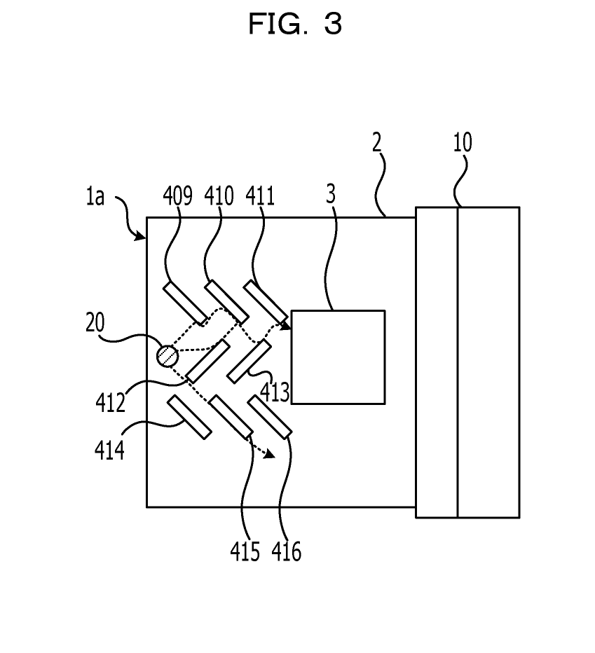

Next, different exemplary arrangements of the resin member 4 (hereinafter referred to as the arrangement pattern) will be described. Each of FIGS. 3, 4, and 5 illustrates a different resin arrangement pattern.

On a substrate unit is illustrated in FIG. 3, resin member 409, 410, 411, 414, 415, and 416, which will often be referred to as the resin member 4, are arranged and tilted to the left side at a predetermined angle relative to a perpendicular direction (a vertical direction defined in FIG. 3). Further, resin member 412 and 413 are arranged and tilted to the right side at a predetermined angle relative to the perpendicular direction.

Each above-described resin member 409, 410, 411, 414, 415, and 416 is arranged at a position determined to distribute an external stress occurring at the stress application point 20 and to reduce the stress acting on the electronic component 3. In FIG. 3, for example, the stress acting on the resin 409 is distributed by the resin 409, and is further distributed by the resin member 410, 413, and 411. Further, the stress acting on the resin 412 is distributed by the resin 412, and is further distributed by the resin member 410, 413, and 411. Further, the stress acting on the resin 415 is distributed by the resin 415 and is led to the rim of the substrate 2.

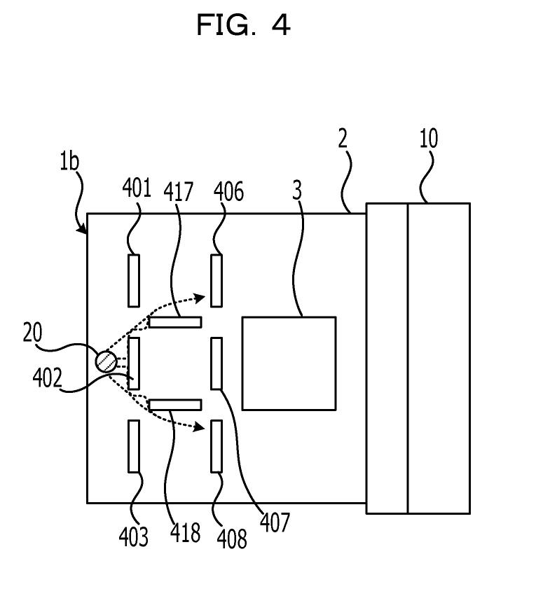

The above-described pattern of arranging the resin member 4 also reduces the stress acting on the electronic component 3. On a substrate unit 1b illustrated in FIG. 4, resin member 417 and 418 are arranged in place of the resin member 404 and 405 that are arranged on the substrate unit 1. The resin member 417 and 418 are arranged at positions where the resin member 404 and 405 would be arranged when the resin member 404 and 405 are rotated 90° about the respective centers of the rectangular shapes of the resin member 404 and 405.

Next, processing procedures performed in the case where an external stress occurs in the substrate unit 1b will be described. When an external stress is applied to the stress application point 20, an external stress is generated in the substrate 2 and is radially propagated through the substrate 2.

When the generated stress acts on the resin member 402, a part of the propagating stress is absorbed by the resin member 402 so that the propagating stress is reduced and moved along the surface of the resin member 402. After that, the propagating stress reaches the corner of the resin member 402 and a part of the propagating stress acts on each resin member 417 and 418.

When the stress acts on each resin member 417 and 418, a part of the propagating stress is absorbed by the resin member 417 and 418 so that the propagating stress is reduced and moved along the surface of each resin member 417 and 418. After that, the stress reaches the corner of the resin 417, and parts of the stress are combined and act on the resin 406. Further, when the stress reaches the corner of the resin 418, parts of the stress are combined and act on the resin 408.

When the stress acts on the resin member 406 and 408, a part of the propagating stress is absorbed by the resin member 406 and 408 so that the propagating stress is reduced and moved along the surface of each resin member 406 and 408. Then, the stress is led to the rim of the substrate 2.

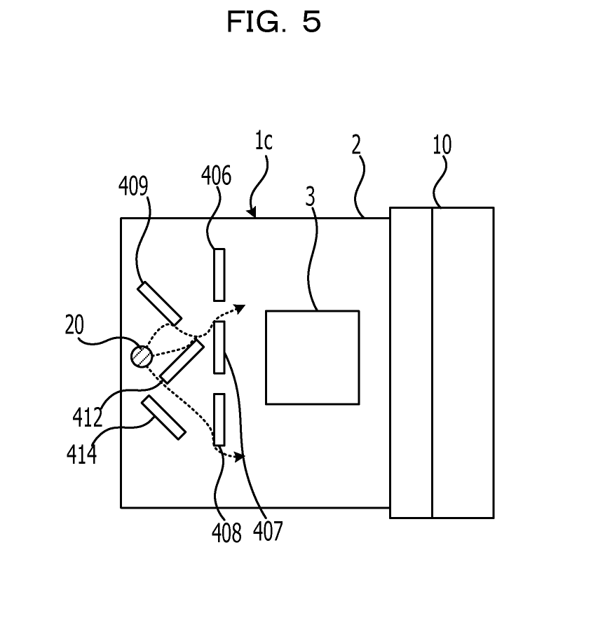

The above-described pattern of arranging the resin member 4 also reduces the stress acting on the electronic component 3. According to a substrate unit is illustrated in FIG. 5, the pattern of arranging the resin member 4, which is illustrated in FIG. 2, and the pattern of arranging the resin member 4, which is illustrated in FIG. 3, are used in combination.

Namely, of the resin member 4 that are arranged on the substrate unit 1, the three resin member 409, 412, and 414 that are arranged on the stress application point 20-side are provided and tilted at a predetermined angle relative to a perpendicular direction. Further, the three resin member 406, 407, and 408 that are arranged on the electronic component 3-side are arranged along the perpendicular direction.

In FIG. 5, for example, an external stress acting on the resin 409 is distributed by the resin 409 and is further distributed by the resin member 412 and 407. Further, the stress acting on the resin 408 is distributed by the resin 408, and is led to the rim of the substrate 2.

The above-described pattern of arranging the resin member 4 also reduces the stress acting on the electronic component 3. In the above-described embodiment, only the stress occurring from the stress application point 20-side has been exemplarily described. However, an external stress also occurs from the supporting member 10-side. Therefore, the resin member 4 may be arranged between the supporting member 10 and the electronic component 3. In that case, the above-described arrangement patterns may be appropriately selected to arrange the resin member 4.

Next, a substrate unit according to a second embodiment is described below. Hereinafter, the difference between the substrate unit of the second embodiment and those of the first embodiment will be mainly described, and the same particulars as those of the first embodiment will be omitted.

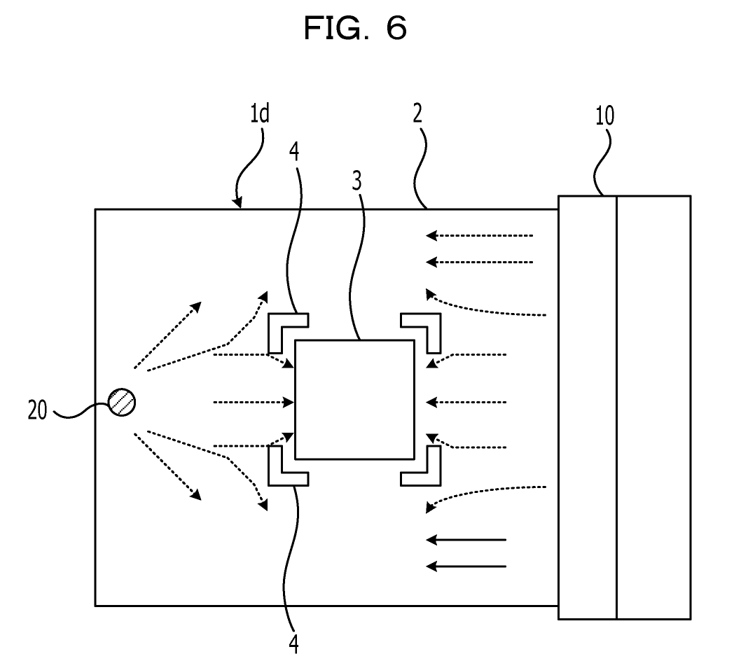

FIG. 6 shows the substrate unit according to the second embodiment. An external stress may occur at a plurality of positions due to the product using condition. Therefore, on the substrate unit 1d, the resin member 4 is arranged to surround the electronic component 3. Namely, on the substrate unit 1d, the resin member 4 is arranged on the supporting member 10-side of the electronic component 3.

Further, each resin member 4 can be in an L-shape (hook shape) and is arranged to cover a corner of the electronic component 3. Consequently, the stress distribution is changed (see the direction in which the stress occurs) to relieve the stress acting on the corner and to reduce the generated stress applied to the corners of the electronic component 3.

Further, the thickness and/or the height of each resin member 4 may be changed to reduce the distortion amount thereof. Further, each resin member 4 may be in a different shape without being limited to the L-shape illustrated in FIG. 6. Hereinafter, exemplarily measured distortion amounts that are attained when the thickness and/or the height of each resin member 4 is changed and when the shape of each resin member 4 is changed to a different shape will be illustrated.

As shown in FIG. 6, an external stress is applied to the stress application point 20 while the substrate unit 1d is held by the supporting member 10 so that a load is applied to the substrate unit 1d. Then, the distortion amount relative to the displacement amount of the substrate 2 is measured. However, the shape of each resin member 4 is changed as discussed below.

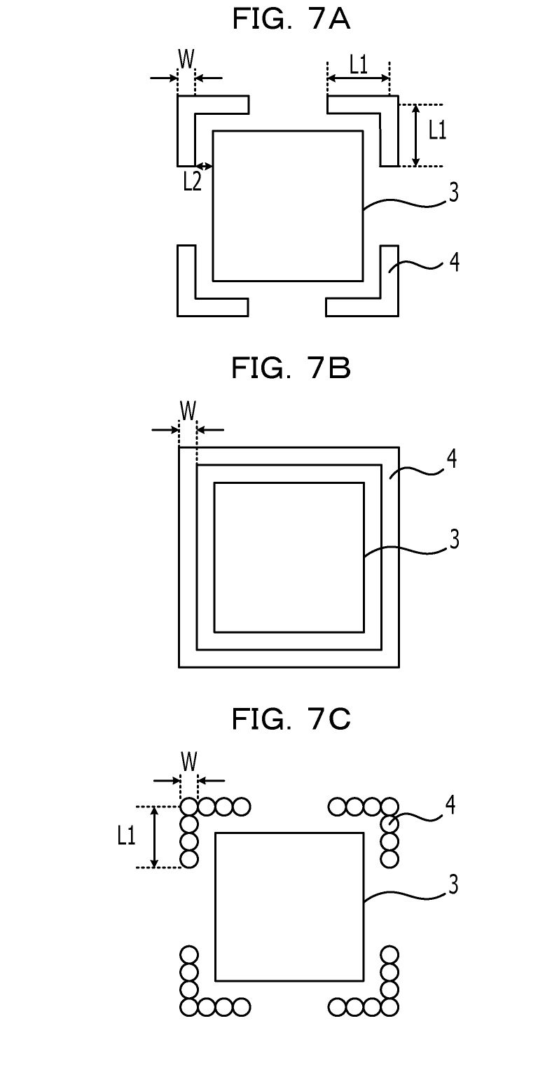

Each of FIGS. 7A, 7B, and 7C illustrates the shape of each resin member 4 for measurement. As illustrated in FIG. 7A, the width and inside diameter of each resin member 4 is indicated with the respective signs W and L1. Further, the distance between an end surface of the electronic component 3 and each resin member 4 is indicated with the sign L2.

The amounts of distortion applied to the vicinity of the electronic component 3, the distortion amounts being attained according to the following arrangement patterns, are compared to one another. Further, a BGA package with dimensions of 34.0×34.0×1.5 mm is used as the electronic component 3.

Arrangement pattern (a): The resin member 4 is not used.

Arrangement pattern (b): Four of the L-shaped resin member 4 is arranged to surround the electronic component 3. The width and height of each resin member 4 is indicated by the respective expressions W=5.0 mm and H=2.5 mm.

Arrangement pattern (c): Four of the L-shaped resin member 4 is arranged to surround the electronic component 3. The width and height of each resin member 4 is indicated by the respective expressions W=2.5 mm and H=2.5 mm.

Arrangement pattern (d): Four of the L-shaped resin member 4 is arranged to surround the electronic component 3. The width and height of each resin member 4 is indicated by the respective expressions W=5.0 mm and H=1.5 mm. According to each above-described arrangement patterns (1) to (4), the lengths L₁ and L₂ of each resin member 4 is respectively determined to be 15 mm and 4.0 mm.

Further, the example where the resin 4 is arranged to cover the entire rim of the electronic component 3 as illustrated in FIG. 7B is studied.

Arrangement pattern (e): The width and height of the resin 4 are indicated by the respective expressions W=2.5 mm and H=1.5 mm.

Further, the example where each resin member 4 is in a dot-shape and a plurality of the resin members 4 is provided as illustrated in FIG. 7C is studied. When the resin 4 is provided as a dot-shaped resin, the resin 4 can be easily shaped.

Arrangement pattern (f): The dot diameter and height of each resin member 4 is indicated by the respective expressions φ=2.5 mm and H=1.5 mm.

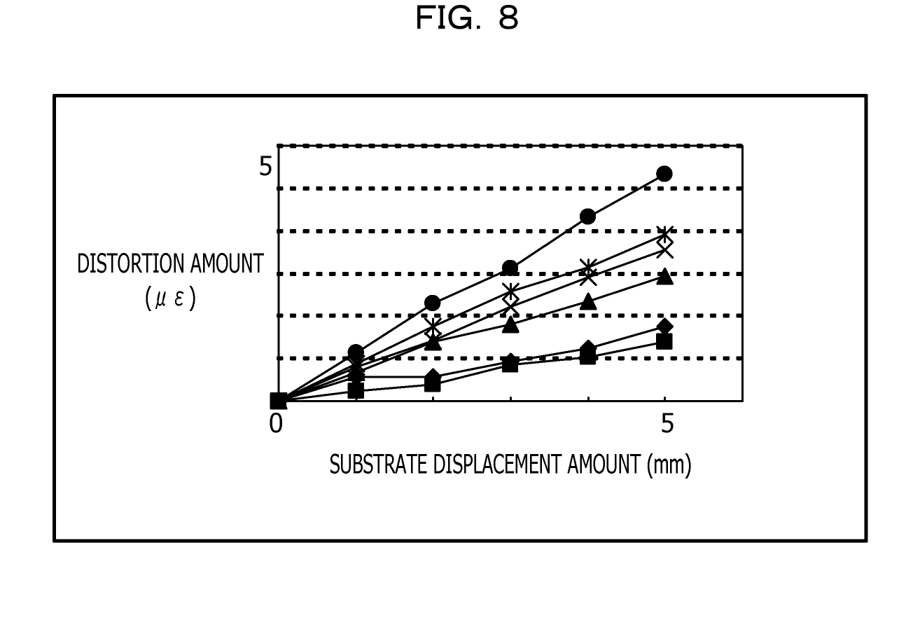

FIG. 8 is a diagram (graph) illustrating the measurement results.

The vertical axis indicates the distortion amount (με) of a substrate 2a and the horizontal axis indicates the displacement amount in millimeter of the substrate 2a. The distortion amount corresponding to the arrangement pattern (a) is plotted as circles. The distortion amount corresponding to the arrangement pattern (b) is plotted as squares. The distortion amount corresponding to the arrangement pattern (c) is plotted as rhombuses. The distortion amount corresponding to the arrangement pattern (d) is plotted as triangles. The distortion amount corresponding to the arrangement pattern (e) is plotted as crosses. The distortion amount corresponding to the arrangement pattern (f) is plotted as asterisks.

When compared to the distortion amount corresponding to the arrangement pattern (a), a measure of success is obtained through each arrangement patterns (2) to (6). For example, the distortion amounts corresponding to the respective arrangement patterns are compared to one another, where each distortion amounts is obtained at the position where the substrate displacement amount is 5 mm.

The displacement amount of the arrangement pattern (b) is decreased 70% or around in relation to that of the arrangement pattern (a). The displacement amount of the arrangement pattern (c) is decreased 60% or around in relation to that of the arrangement pattern (a). The displacement amount of the arrangement pattern (d) is decreased 40% or so in relation to that of the arrangement pattern (a). The displacement amount of the arrangement pattern (e) is decreased 20% or so in relation to that of the arrangement pattern (a). The displacement amount of the arrangement pattern (f) is decreased 20% or so in relation to that of the arrangement pattern (a).

Further, even though the resin member 4 is in the same shape, the width and height of each resin member 4 may be changed at the resin application time so that the obtained effects vary. More specifically, it is confirmed that the distortion amount is decreased with an increase in each width W and the height H.

Further, the relationship between the arrangement patterns (2) and (3) is compared to that between the arrangement patterns (2) and (4). Consequently, it is confirmed that a distortion amount obtained when the height H is doubled (increased) is smaller than that obtained when the width W is doubled (increased). More specifically, it is confirmed that doubling the height H has the effect of reducing (distributing) the stress by 30% or so. Further, it is confirmed that doubling the width W has the effect of reducing (distributing) the stress by 10% or so.

Further, the pattern of arranging the resin member 4 may not be limited to the arrangement patterns (2) to (6), but at least two of the arrangement patterns (2) to (6) may be used in combination. For example, the arrangement patterns (5) and (6) may be used in combination.

Further, the arrangement patterns of the second embodiment and those of the first embodiment may be used in combination. For example, a plurality of stages of the resin members 4 arranged according to the arrangement pattern (b) may be provided in a direction defined from the electronic component 3 toward the rim of the substrate 2.

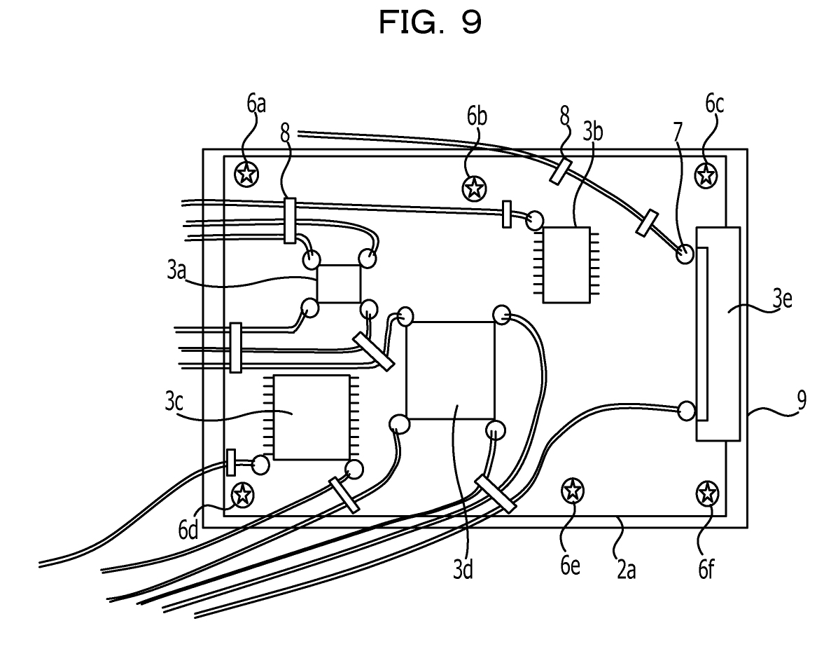

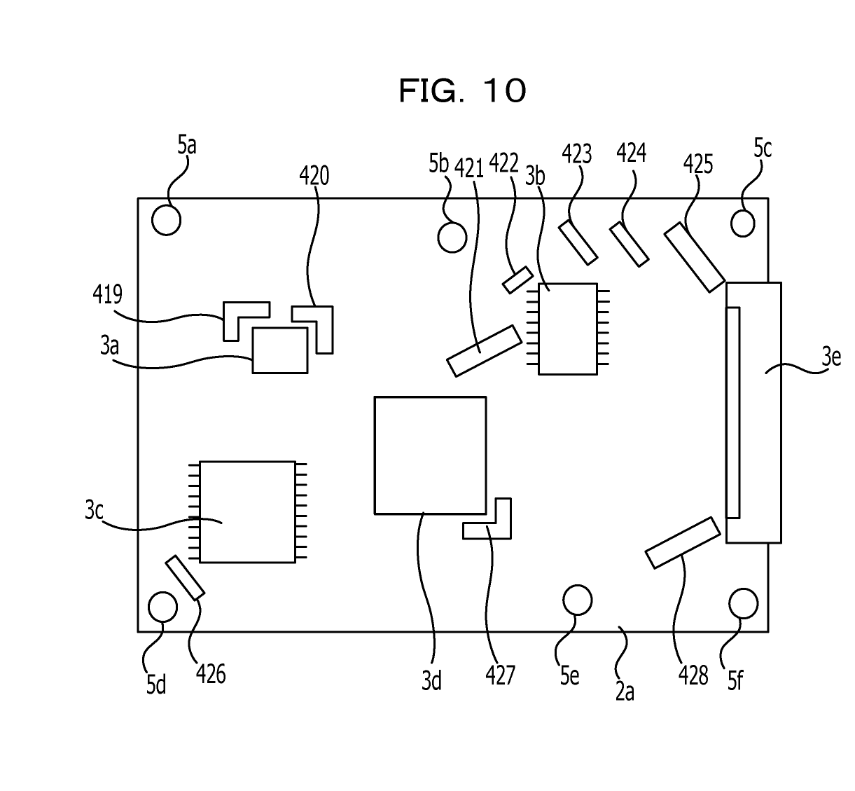

Next, the method of manufacturing the substrate unit will be described with reference to FIGS. 9 and 10.

[Step S1] First, the substrate 2a, provided with holes to accommodate screws is prepared. Then, electronic components 3a, 3b, 3c, 3d, and 3e are soldered and mounted on the prepared substrate 2a.

[Step S2] Since the substrate 2a is screwed to an enclosure 9, each screw position becomes the stress source and an external stress occurs in the substrate 2.

Therefore, a distortion gauge 7 is temporarily adhered to a region where the stress concentration is expected (e.g., a corner portion of each electronic components 3a to 3e) by using an adhesive or the like. Then, the lead wire of each distortion gauges 7 is fixed to the substrate 2a by using a tape 8. Then, a screw is inserted into the screw hole and the substrate 2a is screwed to the enclosure 9. FIG. 9 illustrates the state where the substrate 2a is screwed to the enclosure 9 through the use of screws 6a to 6f.

The substrate 2a is screwed to the enclosure 9 so that an external stress occurs in the substrate 2a. In that state, an external stress occurring in a corner or the like of each electronic component 3a to 3e is actually measured through the distortion gauge 7.

[Step S3] Next, as illustrated in FIG. 10, spots where the resin member 4 is arranged are detected based on a result of the actual measurement of the stresses occurring due to the screws. Further, an appropriate shape (the position, width, height, and so forth) of each resin member 4 is determined for each arrangement spots. An exemplary method of determining the above-described shape will be described later. Further, FIG. 10 illustrates screw holes 5a, 5b, 5c, 5d, 5e, and 5f.

In FIG. 10, it is determined that a resin 419 is arranged so that stresses are not concentrated onto the upper left corner of the electronic component 3a. It is determined that a resin 420 is arranged so that the stresses are not concentrated onto the upper right corner of the electronic component 3a. It is determined that a resin 422 is arranged so that the stresses are not concentrated onto the upper left corner of the electronic component 3b. It is determined that resin member 423, 424, and 425, which form stages, are arranged so that the stresses are not concentrated onto the upper right corner of the electronic component 3b. It is determined that a resin 426 is arranged so that the stresses are not concentrated onto the lower left corner of the electronic component 3c. It is determined that a resin 421 is arranged so that the stresses are not concentrated onto the upper right corner of the electronic component 3d. It is determined that a resin 427 is arranged so that the stresses are not concentrated onto the lower right corner of the electronic component 3d. It is determined that a resin 428 is arranged so that the stresses are not concentrated onto the lower left corner of the electronic component 3e.

[Step S4] Next, a resin is applied to each of the determined spots. Then, the applied resin is cured according to an appropriate method such as the natural drying method, ultraviolet irradiation, heat application, etc. Consequently, the substrate unit is completed.

The description of the method of manufacturing the substrate unit is thus completed. Each above-described substrate units 1 and 1a to 1d can also be manufactured according to the above-described method.

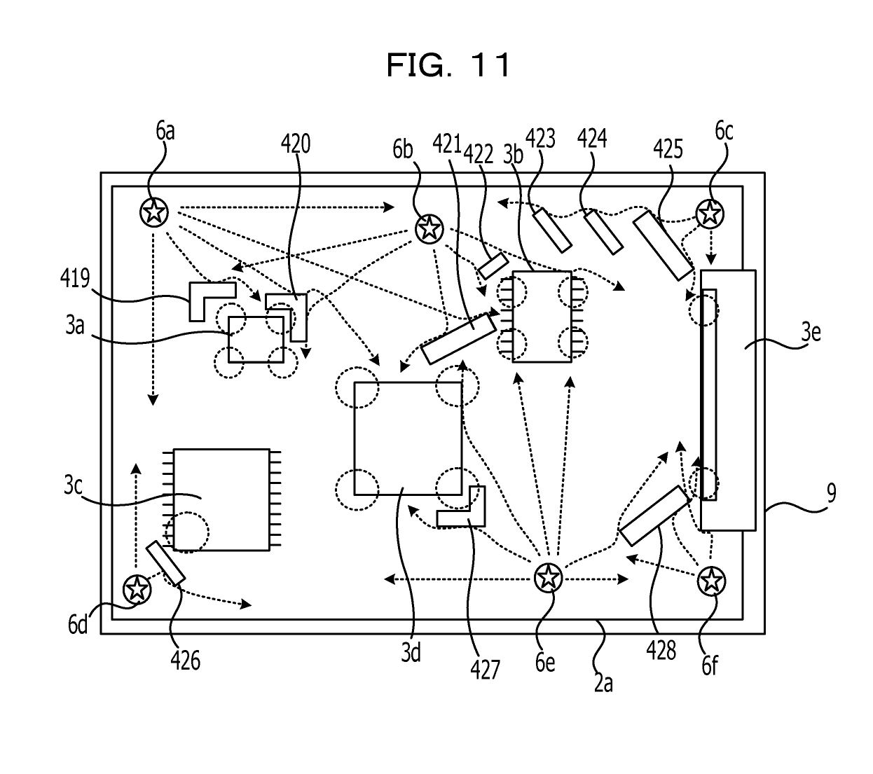

FIG. 11 illustrates an example of stress occurring in a substrate unit manufactured according to the manufacture method of the second embodiment. The arrangement of the resin member 419 to 428 allows for reducing stresses concentrated onto spots (dotted circles shown in FIG. 11) that should be protected from the stress concentration.

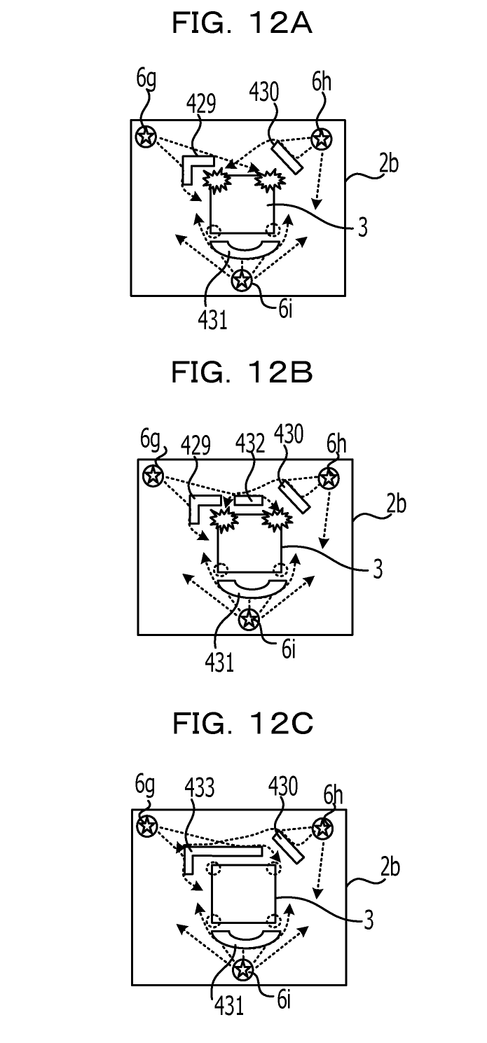

Next, a method of determining the positions where the resin member 4 is arranged, which is performed at step S3, will be described. Each of FIGS. 12A, 12B, and 12C illustrates a method of determining the positions where the resin member 4 is arranged. Hereinafter, the above-described methods will be described in relation to the electronic component 3 arranged on a substrate 2b for the sake of simplification.

[Step S11] The arrangement position and shape of each resin member 4 is determined in relation to each of spots (dotted circles shown in each of FIGS. 12A to 12C) of the electronic component 3, where the spots are closest to the screwing position and should be protected from the stress concentration.

In FIG. 12A, the spot closest to the screwing position for the screw 6g is the upper left corner of the electronic component 3. Therefore, it is determined that an L-shaped resin 429 is arranged near the upper left corner. The spot closest to the screw position for the screw 6h is the upper right corner of the electronic component 3. Therefore, it is determined that a rectangular resin 430 is arranged near the upper right corner. The spot closest to the screw position for the screw 6i is each lower right corner and lower left corner of the electronic component 3. Therefore, it is determined that a U-shaped resin 431 is arranged near the lower right corner and the lower left corner.

[Step S12] A direction in which the stress is distributed (escapes) due to the arrangement of the resin member 429, 430, and 431 is predicted.

When the predicted stress distribution direction is defined toward the spot that should be protected from the stress concentration, the arrangement position and shape of the second resin 4 are determined so that the second resin 4 is arranged. As a result of the arrangement of the resin 4, the stress may be inappropriately distributed due to, for example, the electronic component 3 and/or a different electronic component cutting off the stress distribution direction. Therefore, the arrangement position and shape of the resin 4 are adjusted in consideration of an efficiency with which the resin 4 is applied to the substrate.

More specifically, it is predicted that the arrangement of the resin 429 causes an external stress occurring due to the screw 6g screwed to the substrate 2b to act on the upper right corner of the electronic component 3. Further, it is predicted that the arrangement of the resin 430 causes an external stress occurring due to the screw 6h screwed to the substrate 2b to act on the upper left corner of the electronic component 3. Consequently, it is determined that a resin 432 is arranged to cut off directions in which the above-described stresses are distributed as illustrated in FIG. 12B.

Here, it is preferable that the resin member 429 and 432 be integral with each other in consideration of the application efficiency. It is determined, therefore, that a resin 433 is arranged in actuality as illustrated in FIG. 12C.

On the other hand, it is predicted that an external stress occurring due to the screw 6i screwed to the substrate 2b is appropriately distributed due to the arrangement of the resin 430 and the action of the stress on the electronic component 3 is reduced. Therefore, it is determined that the resin 430 is arranged based on the determination.

[Step S13] When an external stress acting on a spot that should be protected from the stress concentration is high, it is determined to increase the width W and/or the height H of each resin member 430, 431, and 433.

The description of the method of determining the arrangement position is thus completed. Further, the determination method illustrated at steps S11 to S13 is not limited only for use in the processing illustrated at step S3, but may also be used for the case where the visual inspection of the screwing state, the second stress measurement, etc., which are performed after the resin 4 is arranged at step S4, reveal that the shape of the resin 4 should be modified and a new shape of the resin 4 should be added.

Thus, the substrate unit-manufacture method of the above-described embodiment allows for reducing the stresses concentrated onto a spot that should be protected from the stress concentration. When comparing to the case where the substrate unit includes a stiffener engaged thereto by using screws, hole-machining should be performed for the substrate while being limited by wiring provided in the substrate. Further, there is a possibility that a different stress will occur. According to the manufacture method of the above-described embodiment, however, the wiring limitation becomes less serious due to the use of the resin member 4 than in the case where the hole-machining is performed. Further, there is a low possibility that a different stress will occur.

Further, when an adhesive is used to engage the stiffener to the substrate unit, an operation almost equal to the underfill application operation should be performed so that man-hours for manufacture are increased. The manufacture method of the above-described embodiment allows for reducing an increase in the man-hours.

According to the above-described substrate unit-manufacture method, the arrangement position of each resin member 4 is determined by actually measuring the stresses through the use of the distortion gauge 7. Without being limited to the above-described method, however, an external stress occurring at a region (soldered region) where each electronic component 3 comes into contact with the substrate 2a may be predicted through a simulation device so that the positions where the resin member 4 is arranged are determined based on the prediction result.

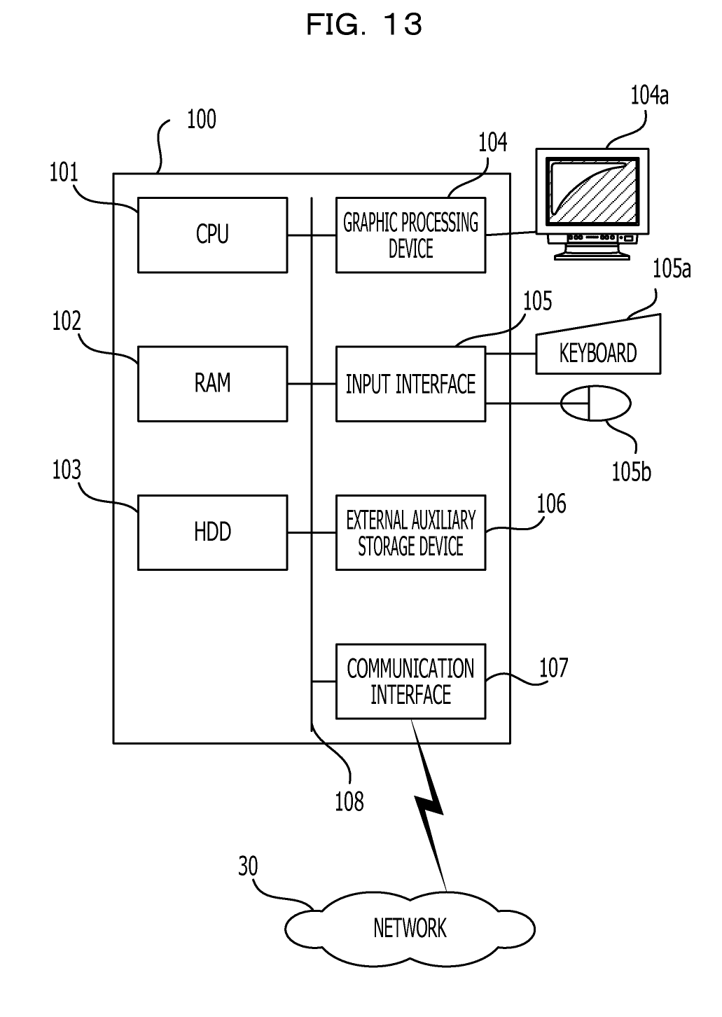

FIG. 13 illustrates an exemplary hardware configuration of a simulation device 100. A CPU 101 can control the entire simulation device 100. A RAM 102, a hard disk drive (HDD) 103, a graphic processing device 104, an input interface 105, an external auxiliary storage device 106, and a communication interface 107 can be connected to the CPU 101 via a bus 108.

At least parts of programs of an operating system (OS), which is executed by the CPU 101, and application programs including, for example, an application program provided to simulate an external stress, is temporarily stored in the RAM 102. Further, various types of data appropriate for processing performed through the CPU 101 is stored in the RAM 102.

The OS and/or the application programs are stored in the HDD 103. Further, program file data is stored in the HDD 103. A monitor 104a is connected to the graphic processing device 104 configured to display image data on the display screen of the monitor 104a based on an instruction issued from the CPU 101. A keyboard 105a and a mouse 105b are connected to the input interface 105 configured to transmit a signal transmitted from the keyboard 105a and/or the mouse 105b to the CPU 101 via the bus 108.

The external auxiliary storage device 106 reads information written onto a recording medium and/or writes information onto the recording medium. A readable and writable recording medium appropriate for the external auxiliary storage device 106 may be, for example, a magnetic recording device, an optical disk, a magneto-optical recording medium, a semiconductor memory, etc. The magnetic recording device may be, for example, an HDD, a flexible disk (FD), a magnetic tape, etc. The optical disk may be, for example, a digital versatile disk (DVD), a DVD-random access memory (RAM), a CD-ROM (compact disk read only memory), a CD-recordable (R)/rewritable (RW), etc. The magneto-optical recording medium may be a magneto-optical disk (MO), for example.

The communication interface 107 is connected to a network 30. The communication interface 107 transmits and/or receives data to and/or from a different computer via the network 30.

The above-described hardware configuration allows for achieving a processing function of the above-described embodiment. Next, the method of manufacturing a substrate unit through the use of the simulation device 100 will be described.

[Step S1a] First, a designer operates the simulation device 100 and starts an application program provided to simulate an external stress. Then, the electronic component is arranged and the screw holes are formed in data of a substrate, the substrate data being displayed on the monitor 104a.

[Step S2] The application program is made to execute a simulation and display data of an external stress occurring in the substrate on the monitor 104a.

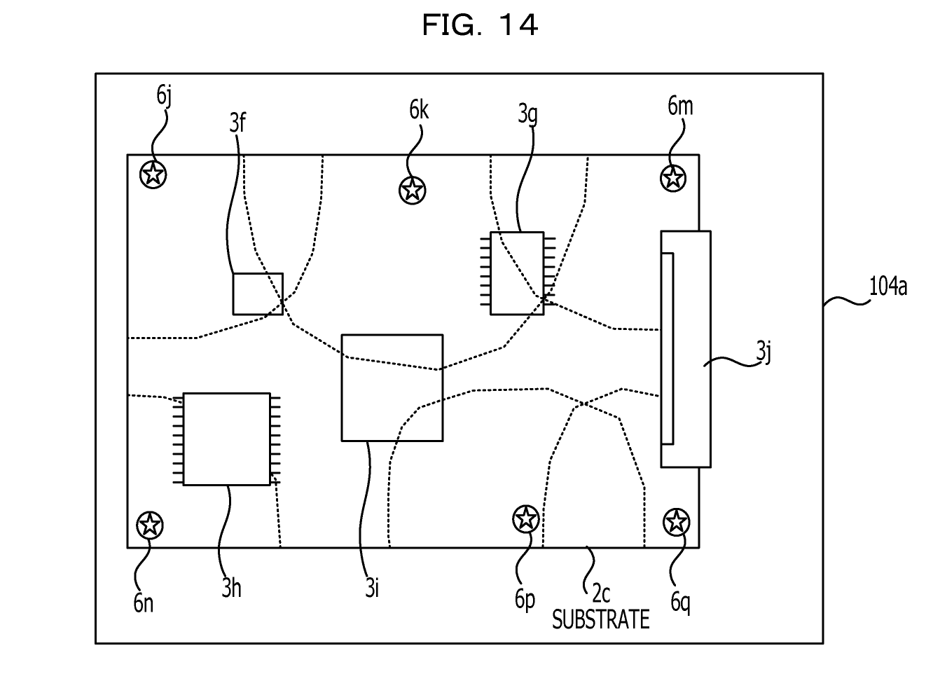

FIG. 14 illustrates the simulation result of which data is displayed on the monitor 104a. Here, a substrate 2c corresponds to the substrate 2a. Electronic components 3f, 3g, 3h, 3i, and 3j correspond to the respective electronic components 3a to 3e. Screws 6j, 6k, 6m, 6n, and 6q correspond to the respective screws 6a to 6e.

FIG. 14 also illustrates each of generated stresses as dotted lines. The intensity of each stresses is expressed, for example, as gradation. Consequently, a user can easily understand on which spot of the electronic component 3 the stresses are concentrated.

Hereinafter, the electronic components 3a to 3e can be arranged on the actual substrate 2a as is the case with the above-described step S1, and the same processing procedures as the above-described steps S3 to S5 are executed. At that time, an appropriate shape (the position, the width, the height, etc.) of the resin 4 is determined based on the simulation result.

Further, the resin may be arranged on the substrate 2c of which data is displayed on the monitor 104a through the use of a resin arrangement function of the application program and the simulation may be performed again. Consequently, it becomes possible to easily perceive an external stress acting on each electronic components 3f to 3j in the state where the resin is arranged.

Thus, the semiconductor device, the method of manufacturing the semiconductor device, and the electronic apparatus of the present invention have been described based on the illustrated embodiments. However, without being limited to the embodiments, the configuration of each components may be replaced with a component which is arbitrarily configured to have the same function as that of the above-described component. Further, the present invention may include an additional different arbitrary structure and/or process.

Further, the present invention may be a combination of at least two arbitrary structures or characteristics that are included in the above-described embodiments. Although the use of the disclosed substrate unit is not particularly limited, the substrate unit may be provided as, for example, a substrate unit mounted to an enclosure included in an electronic apparatus that should be compact in size, such as a mobile terminal device, and/or a substrate unit provided for a flat cable.

Further, the semiconductor device-manufacture method according to the embodiment may be used for an integrated circuit. Incidentally, the above-described simulation function may be achieved through a computer. In that case, a program describing the details of processing performed through the function of the simulation device 100 is provided. The program is executed by a computer so that the above-described processing function is achieved through the computer. The program describing the processing details may be stored in a computer readable recording medium which may be, for example, a magnetic recording device, an optical disk, a magneto-optical recording medium, a semiconductor memory, etc. The magnetic recording device may be, for example, a hard disk device (HDD), a flexible disk (FD), a magnetic tape, etc. The optical disk may be, for example, a digital versatile disk (DVD), a DVD-random access memory (RAM), a CD-ROM (compact disk read only memory), a CD-recordable (R)/rewritable (RW), etc. The magneto-optical recording medium may be a magneto-optical disk (MO), for example.

For distributing a program, a portable recording medium storing the program is sold, where the portable recording medium may be a DVD, a CD-ROM, etc. Further, the program may be stored in the storage of a server computer so that the program is transferred from the server computer to a different computer via a network.

A computer executing a simulation program stores a program recorded onto a portable recording medium and/or a program transferred from a server computer in the storage of the computer. Then, the computer reads the program from the storage thereof and executes processing based on the program. Further, the computer may directly read the program from the portable recording medium and execute processing based on the program. Further, each time the program is transferred from the server computer, the computer may execute processing, one by one, based on the transferred program.

All examples and conditional language recited herein are intended for pedagogical objects to aid the reader in understanding the invention and the concepts contributed by the inventors to further the art, and are to be construed as being without limitation to such specifically recited examples and conditions, nor does the organization of such examples in the specification relate to a showing of the superiority and inferiority of the invention. Although the embodiments of the invention have been described in detail, it will be understood by those of ordinary skill in the relevant art that various changes, substitutions, and alterations could be made hereto without departing from the spirit and scope of the invention as set forth in the claims.

What is claimed is:

1. A semiconductor device comprising:
a substrate including a first electrode;
an electronic component provided on the substrate, the electronic component including a second electrode electrically connected to the first electrode; and
a resin member alleviating an external stress to the second electrode of the electronic component, the resin member disposed on the substrate at a region separated from the electronic component.

2. The semiconductor device according to claim 1, wherein the resin member includes a plurality of resin members alternately located on the substrate.

3. The semiconductor device according to claim 2, wherein the plurality of resin members are alternately located with respect to the electronic component so that the external stress is distributed.

4. The semiconductor device according to claim 1, wherein the resin member is disposed to surround a corner portion of the electronic component.

5. The semiconductor device according to claim 4, wherein the resin member includes a plurality of dot-shaped parts.

6. The semiconductor device according to claim 1, wherein the resin member is disposed to surround a periphery of the electronic component.

7. The semiconductor device according to claim 1, wherein the resin member is provided on a surface of the substrate, the surface being opposed to a surface where the electronic component is located.

8. A manufacture method of a semiconductor device, said method comprising:
providing the semiconductor device, including a substrate and an electronic component disposed thereupon;
disposing a resin member on the substrate at a region separated from the electronic component to alleviate an external stress to a second electrode of the electronic component, the second electrode electrically connected to a first electrode of the substrate.

9. The manufacture method according to claim 8, further comprising:
curing the resin member applied on the substrate.

10. An electronic apparatus, comprising:
an enclosure; and
a semiconductor device installed in the enclosure, wherein the semiconductor device includes a substrate including a first electrode an electronic component provided on the substrate, the electronic component including a second electrode electrically connected to the first electrode; and a resin member alleviating an external stress to the second electrode of the electronic component, the resin member disposed on the substrate at a region separated from the electronic component.
